(19) United States
(12) Patent Application Publication
(10) Pub. No.: US 2014/0355226 A1
(43) Pub. Date: Dec. 4, 2014

(54) ANISOTROPIC CONDUCTIVE FILM LAMINATE, DISPLAY DEVICE HAVING THE SAME, AND METHOD FOR MANUFACTURING THE DISPLAY DEVICE

(71) Applicant: Samsung Display Co., Ltd., Yongin-City (KR)

(72) Inventors: Joon-Sam KIM, Yongin-City (KR); Jong-Hwan KIM, Yongin-City (KR); Sang-Won YEO, Yongin-City (KR)

(73) Assignee: Samsung Display Co., Ltd., Yongin-City (KR)

(21) Appl. No.: 14/160,335

(22) Filed: Jan. 21, 2014

(30) Foreign Application Priority Data
May 28, 2013 (KR) 10-2013-0060597

(51) Int. Cl. H05K 1/11; H05K 3/00; H05K 1/18

(52) U.S. Cl. CPC H05K 1/111; H05K 1/181; H05K 3/0008; H05K 3/0058; H05K 2201/05; H05K 2203/061
USPC 361/749; 361/768; 428/212; 156/64

(57) ABSTRACT

An anisotropic conductive film laminate is provided. The anisotropic conductive film laminate includes a first non-conductive film, an anisotropic conductive film disposed on the first non-conductive film, and a second non-conductive film disposed on the anisotropic conductive film, wherein the first non-conductive film has a higher viscosity than the second non-conductive film, and a lower viscosity than the anisotropic conductive film.

### CROSS-REFERENCE TO RELATED APPLICATION

This application claims priority to and the benefit of Korean Patent Application No. 10-2013-0060597 filed in the Korean Intellectual Property Office on May 28, 2013, the entire contents of which are incorporated herein by reference.

### BACKGROUND

1. Field of Disclosure

The present disclosure relates to a display device. More particularly, the present disclosure relates to the use of an anisotropic conductive film laminate for enabling fine pitch bonding in the display device, and a method of manufacturing the display device.

2. Description of the Related Art

In recent years, various types of display devices have been developed. Examples of these display devices include liquid crystal display (LCD), organic light emitting diode (OLED) display, electrophoretic display, and devices based on other types of display technologies.

A display device typically includes an integrated circuit chip (or a flexible printed circuit substrate) mounted on an edge of a display panel using different packaging means, such as a tape carrier package (TCP), or chip on glass (COG) or chip on film (COF) with an anisotropic conductive film. The resolution of the display device depends in part on the dimensions and pitch of the wires connecting the integrated circuit chip to a substrate. An increase in the resolution of the display device generally requires a corresponding reduction in the dimensions and pitch of the wires.

However, the reduction in dimensions and pitch of the wires may pose certain challenges in the manufacture of the display device. For example, as the dimensions and pitch of the wires decrease, it becomes increasingly difficult to align and bond the integrated circuit chip to the substrate using existing anisotropic conductive films, which may lead to reliability and manufacturing yield issues.

### SUMMARY

The present disclosure is directed to address at least the above problems relating to the manufacture of high resolution display devices using existing anisotropic conductive films.

According to some embodiments of the inventive concept, an anisotropic conductive film laminate is provided. The anisotropic conductive film laminate includes a first non-conductive film, an anisotropic conductive film disposed on the first non-conductive film, and a second non-conductive film disposed on the anisotropic conductive film, wherein the first non-conductive film has a higher viscosity than the second non-conductive film, and a lower viscosity than the anisotropic conductive film.

In some embodiments, the first non-conductive film may have a viscosity ranging from about 1×10⁵ mPa·s to about 1×10⁹ mPa·s, the anisotropic conductive film may have a viscosity ranging from about 1×10⁷ mPa·s to about 1×10¹¹ mPa·s, and the second non-conductive film may have a viscosity ranging from about 1×10³ mPa·s to about 1×10⁷ mPa·s.

In some embodiments, the anisotropic conductive film may include a plurality of conductive particles.

In some embodiments, the conductive particles may have a diameter substantially equal to a thickness of the anisotropic conductive film.

In some embodiments, the conductive particles may have a diameter greater than a thickness of the anisotropic conductive film.

In some embodiments, the conductive particles may have a diameter ranging from about 1 μm to about 10 μm.

According to some other embodiments of the inventive concept, a display device is provided. The display device includes a substrate comprising a mounting region and one or more conductive pads formed in the mounting region, and an external connecting member comprising a connecting region and one or more bumps formed in the connecting region. The substrate and the external connecting member are bonded together at the mounting and connecting regions using an anisotropic conductive film laminate disposed between the conductive pads and bumps. The anisotropic conductive film laminate comprises a first non-conductive film, an anisotropic conductive film disposed on the first non-conductive film, and a second non-conductive film disposed on the anisotropic conductive film, wherein the first non-conductive film has a higher viscosity than the second non-conductive film, and a lower viscosity than the anisotropic conductive film.

In some embodiments, the first non-conductive film may have a viscosity ranging from about 1×10⁵ mPa·s to about 1×10⁹ mPa·s, the anisotropic conductive film may have a viscosity ranging from about 1×10⁷ mPa·s to about 1×10¹¹ mPa·s, and the second non-conductive film may have a viscosity ranging from about 1×10³mPa·s to about 1×10⁷mPa·s.

In some embodiments, the anisotropic conductive film may include a plurality of conductive particles.

In some embodiments, the conductive particles may have a diameter substantially equal to a thickness of the anisotropic conductive film.

In some embodiments, the conductive particles may have a diameter greater than a thickness of the anisotropic conductive film.

In some embodiments, the conductive particle may have a diameter ranging from about 1 μm to about 10 μm.

In some embodiments, the external connecting member may include an integrated circuit chip or a flexible printed circuit substrate (FPCB).

According to some further embodiments of the inventive concept, a method of manufacturing a display device is provided. The method includes applying an anisotropic conductive film laminate onto a connecting region of an external connecting member, wherein the connecting region includes one or more bumps formed in the connecting region; aligning the connecting region of the external connecting member to a mounting region of a substrate, wherein the mounting region includes one or more conductive pads formed in the mounting region, and the connecting region is aligned to the mounting region using the bumps and conductive pads as reference; and bonding the external connecting member to the substrate at the connecting and mounting regions via the anisotropic conductive film laminate.

In some embodiments, bonding the external connecting member to the substrate may further include compressing the substrate and the external connecting member with the anisotropic conductive film laminate interposed therebetween, so as to dispose a number of conductive particles between the conductive pads and the corresponding bumps.

### BRIEF DESCRIPTION OF THE DRAWINGS

FIG. 1 is a cross-sectional view of an anisotropic conductive film laminate according to an embodiment of the inventive concept.

FIG. 2 is a cross-sectional view of an anisotropic conductive film laminate according to another embodiment of the inventive concept.

FIG. 3 is a cross-sectional view of a portion of a display device according to an embodiment of the inventive concept.

FIG. 4 illustrates an exploded view of the elements in the display device of FIG. 3 prior to the manufacture of the display device.

### DETAILED DESCRIPTION

The inventive concept will be more fully described herein with reference to the accompanying drawings, in which different embodiments are shown. As those skilled in the art would realize, the inventive concept is not limited to the described embodiments, and the embodiments may be modified in various ways without departing from the spirit or scope of the present disclosure.

In the drawings, the thicknesses of the layers, films, panels, regions, etc., have been exaggerated for clarity. Like reference numerals designate like elements throughout the specification. It is noted that when an element such as a layer, film, region, or substrate is referred to as being formed “on” another element, it can either be formed directly on the other element, or formed on one or more intervening elements located between the two elements. In contrast, when an element is referred to as being formed “directly on” another element, there is no intervening element present between the two elements.

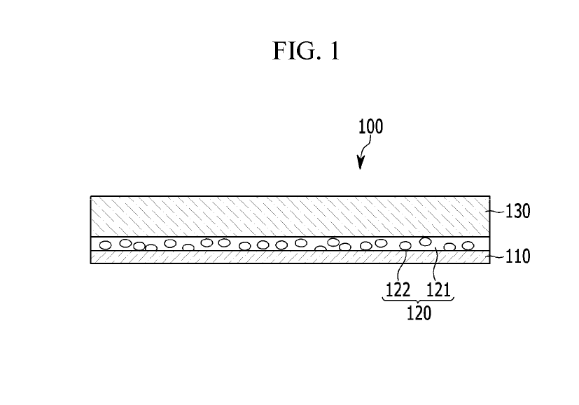

FIG. 1 is a cross-sectional view of an anisotropic conductive film laminate according to an embodiment of the inventive concept.

Referring to FIG. 1, an anisotropic conductive film laminate 100 includes a first non-conductive film 110, an anisotropic conductive film (ACF) 120 disposed on the first non-conductive film 110, and a second non-conductive film 130 disposed on the anisotropic conductive film 120. The anisotropic conductive film 120 includes an adhesive resin 121 and conductive particles 122 embedded within the adhesive resin 121. As shown in FIG. 1, some of the conductive particles 122 may be disposed in contact with the first non-conductive film 110 and/or the second non-conductive film 130.

In the example of FIG. 1, the first non-conductive film 110 is bonded to the second non-conductive film 130 via the adhesive resin 121 in anisotropic conductive film 120. The adhesive resin 121 may include thermosetting resins, such as bisphenol A epoxy resin, bisphenol F epoxy resin, novolac epoxy resin, phenol resin, urea resin, melamine resin, unsaturated polyester resin, resorcinol resin, or other similar types of resins.

As previously described, the anisotropic conductive film 120 includes conductive particles 122. The conductive particles 122 are formed of an electrically conductive material (e.g. a metal), so as to provide electrical conductivity to the anisotropic conductive film laminate 100. The conductive particles 122 may be formed in various shapes. As shown in FIG. 1, the conductive particles 122 may be formed as either round or oval-shaped beads. In some embodiments, the diameter of the conductive particles 122 may range from about 1 μm to about 10 μm. In some particular embodiments, the diameter of the conductive particles 122 may range from about 2.5 μm to about 5 μm.

The first and second non-conductive films 110/130 may include thermosetting adhesive resins, such as bisphenol A epoxy resin, bisphenol F epoxy resin, novolac epoxy resin, phenol resin, urea resin, melamine resin, unsaturated polyester resin, resorcinol resin, and other similar types of resins. In some embodiments, the same type(s) of thermosetting adhesive resins may be used in the first non-conductive film 110 and second non-conductive film 130. In some other embodiments, different types of thermosetting adhesive resins may be used in the first non-conductive film 110 and second non-conductive film 130. The resins in the first and second non-conductive films 110/130 may include the types of resins that can be used for the anisotropic conductive film 120.

The first non-conductive film 110 and second non-conductive film 130 provide adhesion of the anisotropic conductive film laminate 100 to an electrical contact (not shown). The electrical contact may include, for example, an electrode or conductive bump disposed on an integrated circuit chip or substrate.

In some embodiments, the thickness of the first non-conductive film 110 may be equal to or less than the thickness of the second non-conductive film 130. For example, when the second non-conductive film 130 has a thickness of about 10 μm, the first non-conductive film 110 may have a thickness of about 5 μm.

In the example of FIG. 1, the first non-conductive film 110, anisotropic conductive film 120, and second non-conductive film 130 may have different viscosities. For example, the first non-conductive film 110 may have a viscosity ranging from about 1×10⁵mPa·s to about 1×10⁹mPa·s; the anisotropic conductive film 120 may have a viscosity ranging from about 1×10⁷ mPa·s to about 1×10¹¹ mPa·s; and the second non-conductive film 130 may have a viscosity ranging from about 1×10³ mPa·s to about 1×10⁷ mPa·s. In some embodiments, the first non-conductive film 110 may have a higher viscosity than the second non-conductive film 130, but a lower viscosity than the anisotropic conductive film 120. Since the first non-conductive film 110 has a higher viscosity than the second non-conductive film 130, the first non-conductive film 110 may collect conductive particles more efficiently. Since the second non-conductive film 130 has the lowest viscosity (relative to the first non-conductive film 110 and the anisotropic conductive film 120), the second non-conductive film 130 may allow the adhesive resin 121 to be discharged more efficiently. The viscosities of the first non-conductive film 110, anisotropic conductive film 120, and second non-conductive film 130 may be determined by measuring the viscosity of the adhesive resin in each film at a specific temperature. For example, the viscosities of the films may be measured at a temperature of about 100° C. (within an error range of about ±5° C.).

In general, thermosetting adhesive resins become less viscous at higher temperatures and flow at different speeds depending on their respective viscosities (prior to curing). By varying the viscosities of the first non-conductive film 110, anisotropic conductive film 120, and second non-conductive film 130, the flow speed of each film can be controlled during a bonding process, which typically involves applying heat and pressure (e.g. in a thermocompression bonding process) to the films. In particular, the number of conductive particles 122 collected on an electrode can be maximized by controlling the viscosity (flow speed) of each film, as described below.

During the bonding process, the adhesive resins in the first non-conductive film 110, anisotropic conductive film 120, and second non-conductive film 130 are first transformed from gel to liquid prior to being cured. In some embodiments, the anisotropic conductive film 120 has the highest viscosity among the three layers in the anisotropic conductive film laminate 100 (i.e. the anisotropic conductive film 120 has a higher viscosity than the first and second non-conductive films 110/130). As a result of the different viscosities, the phase transformation from gel to liquid of the adhesive resin 121 in the anisotropic conductive film 120 will be delayed relative to the phase transformations (from gel to liquid) of the adhesive resins in the first and third non-conductive films 110/130. As previously stated, the conductive particles 122 are embedded within the adhesive resin 121. Because the adhesive resin 121 starts flowing at a later time (and more slowly) relative to the resins in the first and third non-conductive films 110/130, the initial distribution of the conductive particles 122 in the anisotropic conductive film 120 can be maintained for a longer period of time during the bonding process. In other words, the reduced fluidity of the adhesive resin 121 reduces the movement/displacement of the conductive particles 122 during the bonding process. Accordingly, the number of conductive particles 122 collected on an electrode can be maximized using the above-described embodiments.

When the anisotropic conductive film laminate 100 is used in the bonding process, the electrical contact (e.g. a bump or electrode) on an integrated circuit chip will protrude into the second non-conductive film 130 during the bonding process. If the second non-conductive film 130 is too viscous, the second non-conductive film 130 will not be adequately displaced during the bonding process, which may subsequently result in electrical opens. Accordingly, in some embodiments, the second non-conductive film 130 has the lowest viscosity among the three layers in laminate 100, so as to ensure that the electrical contact makes contact with the underlying anisotropic conductive film 120 and the opposing electrical pad on the substrate.

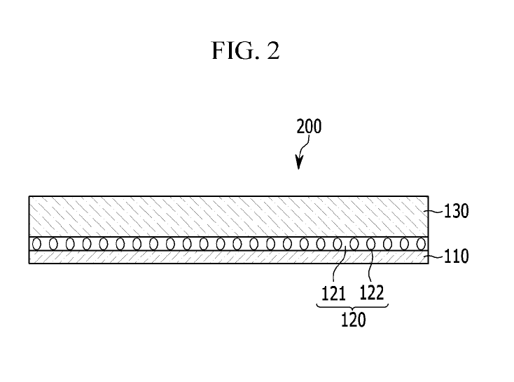

FIG. 2 is a cross-sectional view of an anisotropic conductive film laminate 200 according to another embodiment of the inventive concept. In the example of FIG. 2, the conductive particles 122 are formed having a diameter that is substantially equal to the thickness of anisotropic conductive film 120. In some embodiments, the diameter of the conductive particles 122 may be substantially equal to the thickness of anisotropic conductive film 120 (within an error range of about 0.5 μm). Accordingly, greater uniformity in the distribution of the conductive particles 122 within resin 121 can be achieved (as shown in FIG. 2). The uniform distribution also increases the collecting efficiency of the conductive particles 122, which allows wires with fine dimensions and pitches to be fabricated, so as to enable high resolution display devices.

In some cases, the diameter of the conductive particles 122 may be greater than the thickness of the anisotropic conductive film 120 (not shown). In those cases, the anisotropic conductive film 120 may be provided with a higher viscosity (relative to the first and third non-conductive films 110/130), so as to reduce the fluidity of the adhesive resin 121. As previously described, the reduced fluidity of the adhesive resin 121 reduces the movement/displacement of the conductive particles 122 during the bonding process, thereby maximizing the number of conductive particles 122 collected on the electrode.

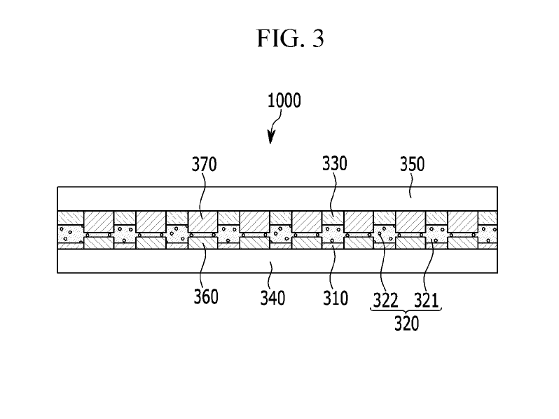

FIG. 3 is a cross-sectional view of a portion of a display device according to an embodiment of the inventive concept. The display device may include a liquid crystal display (LCD), organic light emitting diode (OLED) display, plasma display, electric field effect display device, electrophoretic display, or other types of display devices.

Referring to FIG. 3, a display device 1000 includes a substrate 340 having a plurality of conductive pads 360 and an external connecting member 350 having a plurality of bumps 370. The conductive pads 360 and bumps 370 are disposed on corresponding locations of the substrate 340 and external connecting member 350, respectively. The display device 1000 further includes an anisotropic conductive film laminate 300 disposed between the conductive pads 360 and bumps 370.

The substrate 340 may be divided into a display area and a non-display area surrounding the display area. A display element (not shown) may be formed in the display area of the substrate 340. The display element may include an organic light emitting display element, a liquid crystal display, an electrophoresis display element, or other types of display elements. A portion of the non-display area may be designated as a mounting region. The mounting region may be disposed on an edge of the substrate 340.

In the example of FIG. 3, the conductive pads 360 may be formed in the mounting region of substrate 340, and configured to be connected to the external connecting member 350. The external connecting member 350 may include, for example, an integrated circuit chip or a flexible printed circuit substrate (FPCB). The external connecting member 350 includes a connecting region to be bonded with the mounting region of substrate 340. The bumps 370 may be formed in the connecting region of the external connecting member 350. The bumps 370 on the external connecting member 350 are disposed facing the conductive pads 360 on substrate 340, and are electrically connected to the conductive pads 360 through the anisotropic conductive film laminate 300.

With reference to FIG. 3, the anisotropic conductive film laminate 300 includes a first non-conductive film 310, an anisotropic conductive film 320, and a second non-conductive film 330. The anisotropic conductive film 320 includes an adhesive resin 321 and conductive particles 322 embedded within the adhesive resin 321. The anisotropic conductive film laminate 300 includes elements similar to those described previously in FIGS. 1 and 2, and thus detailed description of those elements shall be omitted.

The substrate 340 and external connecting member 350 are bonded together using the anisotropic conductive film laminate 300, which provides both electrical connectivity and mechanical support.

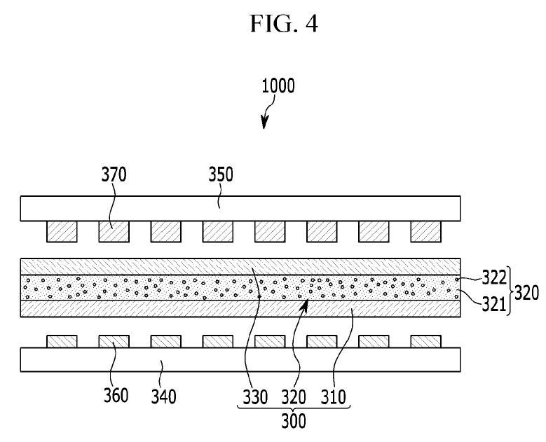

Next, a method of manufacturing an exemplary display device will be described with reference to FIG. 4.

FIG. 4 illustrates an exploded view of the elements in the display device of FIG. 3 prior to the manufacture of the display device. Specifically, the manufacture of the display device includes the assembly of the different elements depicted in FIG. 4.

With reference to FIG. 4, a substrate 340 and an external connecting member 350 are provided. As previously described, the substrate 340 includes a plurality of conductive pads 360 formed in a mounting region of the substrate 340, and the external connecting member 350 includes a plurality of bumps 370 formed in a connecting region of the external connecting member 350.

Next, an anisotropic conductive film laminate 300 is provided. The anisotropic conductive film laminate 300 includes a first non-conductive film 310, an anisotropic conductive film 320, and a second non-conductive film 330. The anisotropic conductive film 320 includes an adhesive resin 321 and conductive particles 322 embedded within the adhesive resin 321. The dimensions of the elements in the anisotropic conductive film laminate 300 may be provided as follows.

In a first embodiment of the anisotropic conductive film laminate (e.g. manufactured by Dexerials), the first non-conductive film 310 may have a thickness of about 4 μm; the anisotropic conductive film 320 may have a thickness of about 8 μm; the second non-conductive film 330 may have a thickness of about 10 μm; and the conductive particles 322 may have a diameter of about 3.2 μm.

In a second embodiment, the first non-conductive film 310 may have a thickness of about 4 μm; the anisotropic conductive film 320 may have a thickness of about 3.2 μm; the second non-conductive film 330 may have a thickness of about 10 μm; and the conductive particles 322 may have a diameter of about 3.2 μm. It is noted that the second embodiment is representative of the anisotropic conductive film laminate 200 in FIG. 2, in which the diameter of the conductive particles is substantially equal to the thickness of anisotropic conductive film.

In a third embodiment, the first non-conductive film 310 may have a thickness of about 5 μm; the anisotropic conductive film 320 may have a thickness of about 3 μm; the second non-conductive film 330 may have a thickness of about 10 μm; and the conductive particles 322 may have a diameter of about 3.2 μm.

In each of the above-described embodiments, the anisotropic conductive film 320 may have a viscosity of about 10⁹ mPa·s; the first non-conductive film 310 may have a viscosity of 10⁷mPa·s; and the second non-conductive film 330 may have a viscosity of 10⁵mPa·s, wherein the viscosity of each of the above film layer is measured at a temperature of about 100° C.

Next, the anisotropic conductive film laminate 300 may be laminated on a surface of the external connecting member 350 over the bumps 370. In some particular embodiments, the anisotropic conductive film laminate 320 may be laminated on a surface of the substrate 340 over the conductive pads 360.

Next, the substrate 340 and external connecting member 350 are aligned (using the bumps 370 and conductive pads 360 as reference) and brought into proximate contact with each other, with the anisotropic conductive film laminate 300 interposed between the substrate 340 and external connecting member 350.

Next, the substrate 340 and external connecting member 350 are bonded together using a bonding process to form the display device of FIG. 3. The bonding process may include applying heat and/or pressure (thermocompression) to the aligned structure of FIG. 4. At the end of the bonding process, electrical connections between the substrate 340 and external connecting member 350 are formed when the bumps 370 and conductive pads 360 are brought into contact with conductive particles 322 interposed therebetween.

As previously described, the adhesive resins in the first non-conductive film 310, anisotropic conductive film 320, and second non-conductive film 330 become less viscous and undergo phase transformations from gel to liquid when heat and/or pressure is applied. During the bonding process, the liquid resins flow and fill in the space between the bumps 360 and conductive pads 360, as well as the gap between the substrate 340 and external connecting member 350. In some embodiments, the anisotropic conductive film 320 has the highest viscosity (relative to the first and second non-conductive films 310/330). As a result, the phase transformation from gel to liquid of the adhesive resin 321 in the anisotropic conductive film 320 will be delayed relative to the phase transformations (from gel to liquid) of the adhesive resins in the first and third non-conductive films 310/330. The resins flow at different rates during the bonding process, with the flow rate of the adhesive resin 321 being the slowest (relative to the resins in the first and second non-conductive films 310/330). Accordingly, the slow flow rate and delayed phase transformation of the adhesive resin 321 limit the motion/displacement of the conductive particles 322 during the bonding process. As such, the initial distribution of the conductive particles 322 in the anistropic conductive film 320 can be maintained for a longer period of time during the bonding process. Accordingly, the number of conductive particles 322 collected between the conductive pads 360 and bumps 370 can be maximized. Furthermore, the above-described embodiments allow fine-pitched electrical connections to be formed, thereby enabling high resolution display devices.

In some embodiments, the first non-conductive film 310 may be omitted from the anisotropic conductive film laminate 300 so as to form a two-layer laminate structure. However, it is noted that the number of conductive particles 322 collected between the conductive pads 360 and bumps 370 may be fewer in a two-layer laminate structure compared to a three-layer laminate structure. For example, in some embodiments, the number of conductive particles collected between the conductive pads and the bumps is 10% more in a three-layer laminate structure compared to a two-layer laminate structure.

While this inventive concept has been described in connection with what is presently considered to be practical exemplary embodiments, it is to be understood that the inventive concept is not limited to the disclosed embodiments, but, on the contrary, is intended to cover various modifications and equivalent arrangements included within the spirit and scope of the disclosure.

What is claimed is:

1. An anisotropic conductive film laminate comprising:
a first non-conductive film,
an anisotropic conductive film disposed on the first non-conductive film, and
a second non-conductive film disposed on the anisotropic conductive film,
wherein the first non-conductive film has a higher viscosity than the second non-conductive film, and a lower viscosity than the anisotropic conductive film.

2. The anisotropic conductive film laminate of claim 1, wherein the first non-conductive film has a viscosity ranging from about 1×10⁵ mPa·s to about 1×10⁹ mPa·s, the anisotropic conductive film has a viscosity ranging from about 1×10⁷mPa·s to about 1×10¹¹mPa·s, and the second non-conductive film has a viscosity ranging from about 1×10³ mPa·s to about 1×10⁷mPa·s.

3. The anisotropic conductive film laminate of claim 1, wherein the anisotropic conductive film comprises a plurality of conductive particles.

4. The anisotropic conductive film laminate of claim 3, wherein the conductive particles have a diameter substantially equal to a thickness of the anisotropic conductive film.

5. The anisotropic conductive film laminate of claim 3, wherein the conductive particles have a diameter greater than a thickness of the anisotropic conductive film.

6. The anisotropic conductive film laminate of claim 1, wherein the conductive particles have a diameter ranging from about 1 μm to about 10 μm.

7. A display device comprising:
a substrate comprising a mounting region and one or more conductive pads formed in the mounting region, and
an external connecting member comprising a connecting region and one or more bumps formed in the connecting region,
wherein the substrate and the external connecting member are bonded together at the mounting and connecting regions using an anisotropic conductive film laminate disposed between the conductive pads and bumps,
the anisotropic conductive film laminate comprising a first non-conductive film, an anisotropic conductive film disposed on the first non-conductive film, and a second non-conductive film disposed on the anisotropic conductive film, and
the first non-conductive film has a higher viscosity than the second non-conductive film, and a lower viscosity than the anisotropic conductive film.

8. The display device of claim 7, wherein the first non-conductive film has a viscosity ranging from about 1×10⁵mPa·s to about 1×10⁹mPa·s, the anisotropic conductive film has a viscosity ranging from about 1×10⁷mPa·s to about 1×10¹¹ mPa·s, and the second non-conductive film has a viscosity ranging from about 1×10³mPa·s to about 1×10⁷mPa·s.

9. The display device of claim 7, wherein the anisotropic conductive film comprises a plurality of conductive particles.

10. The display device of claim 9, wherein the conductive particles have a diameter substantially equal to a thickness of the anisotropic conductive film.

11. The display device of claim 9, wherein the conductive particles have a diameter greater than a thickness of the anisotropic conductive film.

12. The display device of claim 9, wherein the conductive particles have a diameter ranging from about 1 μm to about 10 μm.

13. The display device of claim 7, wherein the external connecting member includes an integrated circuit chip or a flexible printed circuit substrate (FPCB).

14. A method of manufacturing a display device, the method comprising:
applying an anisotropic conductive film laminate onto a connecting region of an external connecting member, wherein the connecting region includes one or more bumps formed in the connecting region;
aligning the connecting region of the external connecting member to a mounting region of a substrate, wherein the mounting region includes one or more conductive pads formed in the mounting region, and the connecting region is aligned to the mounting region using the bumps and conductive pads as reference; and
bonding the external connecting member to the substrate at the connecting and mounting regions via the anisotropic conductive film laminate.

15. The method of claim 14, wherein the anisotropic conductive film laminate comprises:
a first non-conductive film,
an anisotropic conductive film disposed on the first non-conductive film, and
a second non-conductive film disposed on the anisotropic conductive film,
wherein the first non-conductive film has a higher viscosity than the second non-conductive film, and a lower viscosity than the anisotropic conductive film.

16. The method of claim 15, wherein the anisotropic conductive film comprises a plurality of conductive particles.

17. The method of claim 16, wherein bonding the external connecting member to the substrate further comprises:
compressing the substrate and the external connecting member with the anisotropic conductive film laminate interposed therebetween, so as to dispose a number of conductive particles between the conductive pads and the corresponding bumps.

18. The method of claim 14, wherein the external connecting member includes an integrated circuit chip or a flexible printed circuit substrate.

19. The method of claim 15, wherein the first non-conductive film has a viscosity ranging from about 1×10⁵ mPa·s to about 1×10⁹ mPa·s, the anisotropic conductive film has a viscosity ranging from about 1×10⁷ mPa·s to about 1×10¹¹ mPa·s, and the second non-conductive film has a viscosity ranging from about 1×10³mPa·s to about 1×10⁷mPa·s.
